(19) United States
(12) Patent Application Publication
(10) Pub. No.: US 2015/0016065 A1
(43) Pub. Date: Jan. 15, 2015

(54) ELECTRONIC DEVICE HAVING MOVABLE DISPLAY

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: XIN YANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/956,312

(22) Filed: Jul. 31, 2013

(30) Foreign Application Priority Data
Jul. 15, 2013 (CN) 2013102942116

(51) Int. Cl. H05K 5/02

(52) U.S. Cl. CPC H05K 5/0217
USPC 361/727

(57) ABSTRACT

An electronic device includes a base, a display slidably covering the base, a slide apparatus installed between the base and the display, and an operation apparatus. The slide apparatus includes a rack mounted to the display, a gear pivotably installed in the base, and a pole protruding out from the gear. The operation apparatus includes an operation member slidably installed on the base and an adjusting member rotatably connected between the operation member and the pole. The rack is engaged with the gear. An axis of the pole deviates from an axis of the gear. The operation member is slid to drive the adjusting member to rotate the gear.

### BACKGROUND

1. Technical Field

The disclosure relates to an electronic device with a movable display.

2. Description of Related Art

Usually, displays of electronic devices are movable for convenient operation and to save space. For example, a clamshell mobile phone generally has a main body and a display slidably mounted to the main body. The displays are pushed relative to the main body by fingers of the operator abutting against the displays. However, the displays are easily abraded, which is unsightly.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of an electronic device, wherein the electronic device includes a slide apparatus and an operation apparatus.

FIG. 2 is an exploded, isometric view of the slide apparatus of FIG. 1.

FIG. 3 is an exploded, isometric view of the operation apparatus of FIG. 1.

FIG. 4 is a partially assembled, isometric view of FIG. 1.

FIG. 5 is an assembled, isometric view of FIG. 1.

FIG. 6 is a cross-sectional view of FIG. 5, taken along the line of VI-VI.

FIG. 7-8 are similar to FIG. 6, but showing two different states of the electronic device of FIG. 1.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean “at least one.”

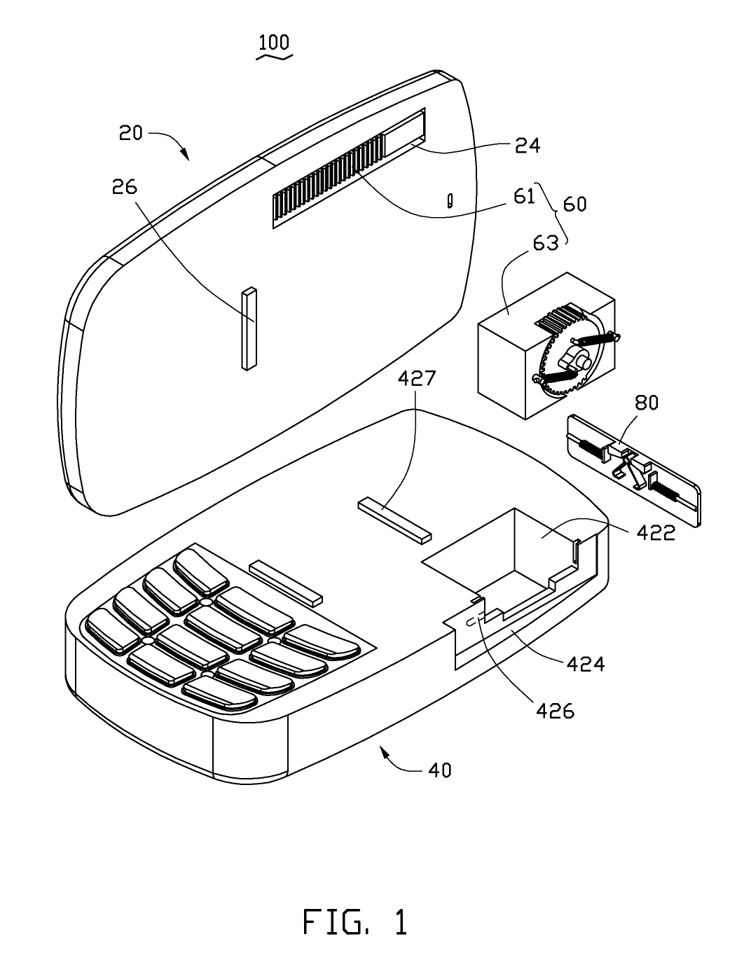

FIG. 1 shows an electronic device 100 includes a display 20, a base 40, a slide apparatus 60, and an operation apparatus 80.

A bottom surface of the display 20 defines a long receiving slot 24 extending along a lengthwise direction of the display 20. The receiving slot 24 is located in a side of a front end of the display 20. A positioning bar 26 protrudes down from a middle of the bottom surface of the display 20, and extends along a widthwise direction of the display 20.

A top surface of the base 40 defines a rectangular receiving space 422. The receiving space 422 is located in a side of a front end of the base 40. The side of the base 40 defines a guiding slot 424 communicating with the receiving space 422. The base 40 defines two opposite guiding holes 426 in a junction of the receiving space 422 and the guiding slot 424. Two spaced stopping bars 427 protrude up from a middle of the top surface of the base 40, and are arranged in a fore-and-aft direction of the base 40.

The slide apparatus 60 includes a rack 61 mounted in the receiving slot 24 of the display 20 and a transmission mechanism 63.

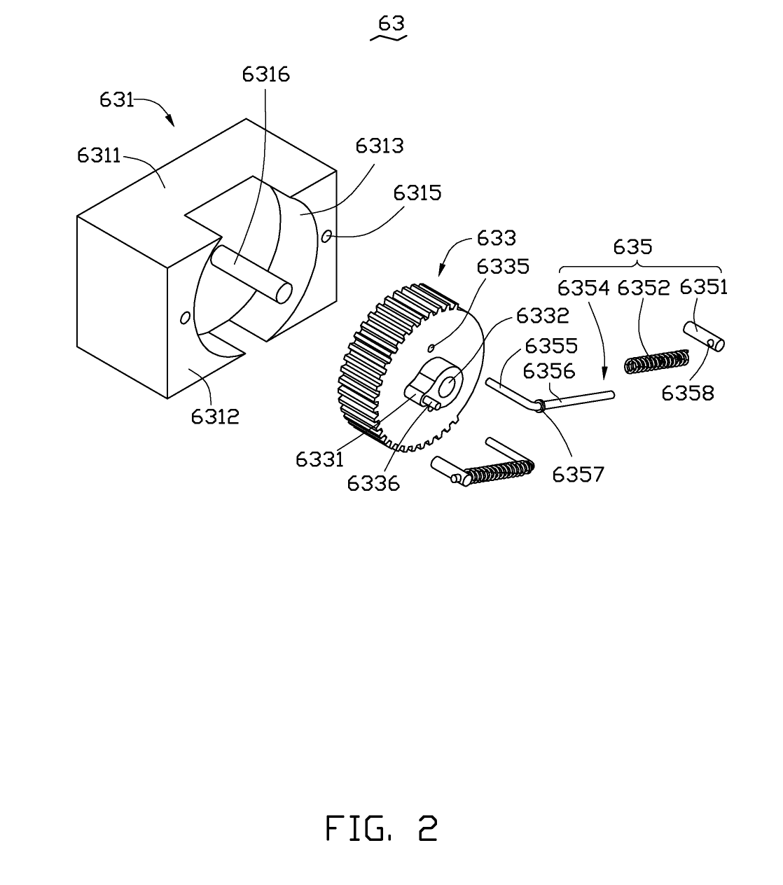

FIG. 2 shows the transmission mechanism 63 includes a bracket 631, a gear 633, and two resilient assemblies 635.

The bracket 631 is substantially rectangular, and includes a top surface 6311 and a side surface 6312 extending down from a side of the top surface 6311. A middle of the side surface 6312 defines a circular recess 6313. The recess 6313 extends through the top surface 6311. Two opposite ends of the side surface 6312 defines two opposite rotation holes 6315 adjacent to the recess 6313. A shaft 6316 perpendicularly extends out from a middle of an inner wall of the recess 6313 opposite to the side surface 6312. An axis of the shaft 6316 is coaxial with an axis of the recess 6313.

A cam-shaped protrusion 6331 protrudes out from a middle of a side of the gear 633. The protrusion 6331 includes a first portion aligning with a middle of the gear 633 and a second portion protruding out from a side of the first portion. The first portion is greater than the second portion in size. The middle of the gear 633 axially defines a shaft hole 6332 extending through the first portion of the protrusion 6331. The gear 633 defines two opposite connecting holes 6335 at two opposite sides of the protrusion 6331. A pole 6336 protrudes out from the second portion of the protrusion 6331. An axis of the pole 6336 deviates from the axis of the gear 633.

Each resilient assembly 635 includes a rotating pole 6351, a first resilient member 6352, and a substantially L-shaped connecting member 6354. An end of the rotating pole 6351 radially defines a through hole 6358. The connecting member 6354 includes a pivot 6355, a connecting pole 6356 perpendicularly extending out from an end of the pivot 6355, and a shrink-ring 6357 mounted on an end of the connecting pole 6356 and adjacent to the pivot 6355. In the embodiment, the first resilient member 6352 is a coil spring.

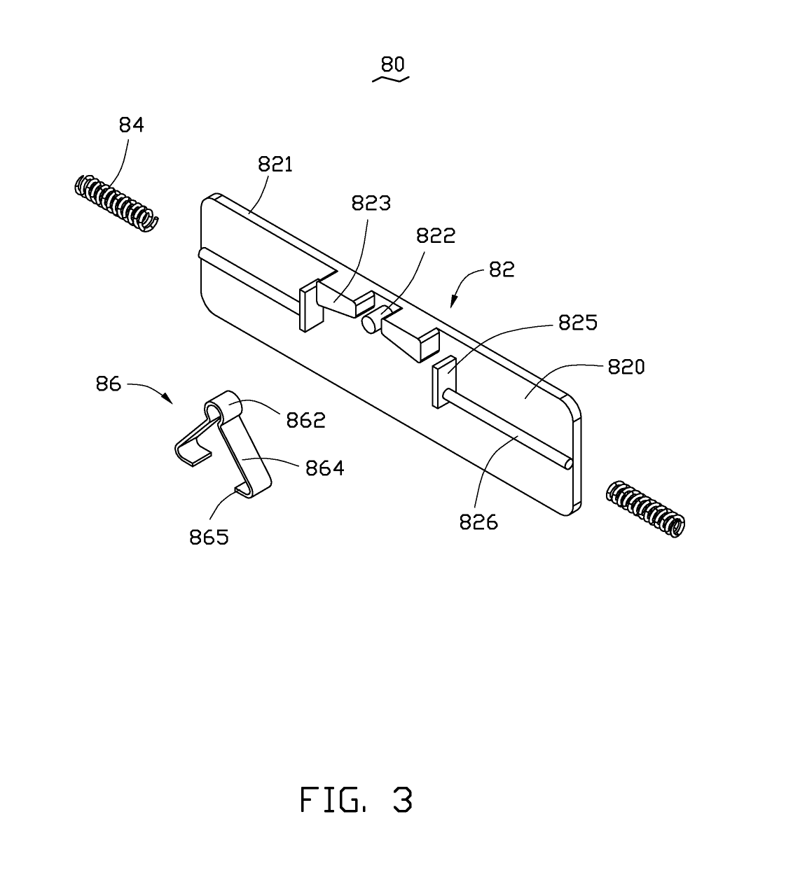

FIG. 3 shows the operation apparatus 80 includes an operation member 82, two second resilient members 84, and an adjusting member 86.

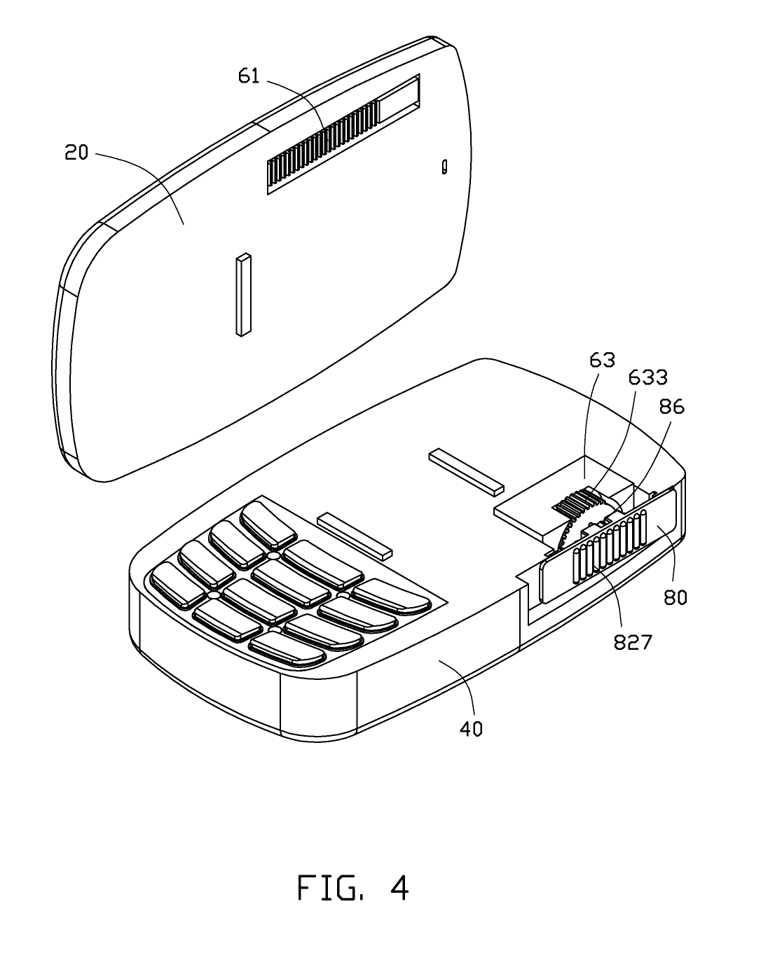

The operation member 82 includes a rectangular sliding plate 821, the sliding plate 821 includes an inner side surface 820. A connecting shaft 822 perpendicularly protrudes out from a middle of an upper side of the inner side surface 820. Two opposite tabs 823 protrude out from the inner side surface 820, and are located at two opposite sides of the connecting shaft 822. Two pieces 825 protrude out from a middle of the inner side surface 820, and adjacent to the tabs 823. Two guiding poles 826 extend from the pieces 825 away from each other. Each guiding pole 826 is spaced and parallel to the sliding plate 821. A plurality of skid-proof bars 827 protrudes out from an outer side surface of the sliding plate 821 opposite to the inner side surface 820 (shown in FIG. 4).

In the embodiment, each second resilient member 84 is a coil spring.

The adjusting member 86 is substantially triangular and includes a substantially C-shaped rotation portion 862, two connecting pieces 864 slantingly extending down from two opposite distal ends of the rotation portion 862 and away from each other, and two hooks 865 formed on distal ends of the connecting pieces 864. The hooks 865 extend toward each other.

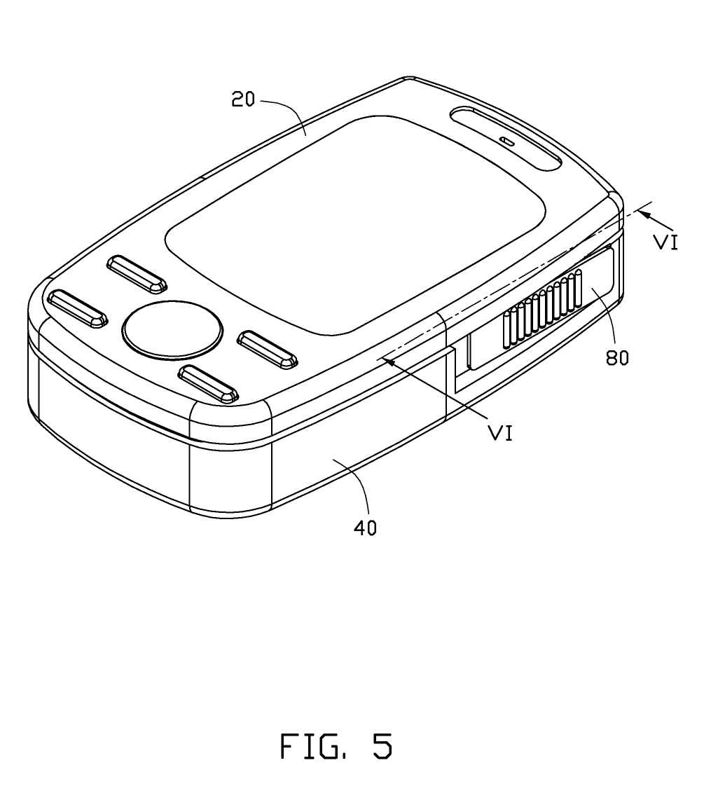

FIGS. 4 and 5 show that in assembly of the electronic device 100, the shaft 6316 of the bracket 631 is inserted in the shaft hole 6332 of the gear 633 from a side surface of the gear 633 opposite to the protrusion 6331. The gear 633 is received in the recess 6313, and a portion of gear 633 is exposed out of the top surface 6311 of the bracket 631. The first resilient members 6352 fit about the connecting poles 6356 of the connecting members 6354, distal ends of the connecting poles 6356 are inserted into the through holes 6358 of the rotating poles 6351. The pivots 6355 of the connecting members 6354 are pivotably inserted into the connecting holes 6335 of the gear 633.

The rotating poles 6351 are pivotably inserted into the rotation holes 6315 of the bracket 631. Thus, each first resilient member 6352 is sandwiched between the shrink-ring 6357 and the corresponding rotating pole 6351.

In assembly of the operation apparatus 80, the second resilient members 84 are fitted about the guiding poles 826 of the operation member 82. The rotation portion 862 of the adjusting member 86 is fitted about the connecting shaft 822 of the operation member 82.

The transmission mechanism 63 is received in the receiving space 422 of the base 40, the pole 6336 is received in the guiding slot 424 of the base 40, and the portion of gear 633 is exposed out of the top surface of the base 40. The operation apparatus 80 is received in the guiding slot 424 of the base 40, and distal ends of the guiding poles 826 are inserted into the guiding holes 426 of the base 40. The second resilient members 84 are sandwiched between the pieces 825 and the base 40. The pole 6336 of the gear 633 is located between the hooks 865 of the adjusting member 86. The display 20 is covered on the base 40, to allow the rack 61 to engage with the gear 633. The positioning bar 26 is stopped between the stopping bars 427 of the base 40.

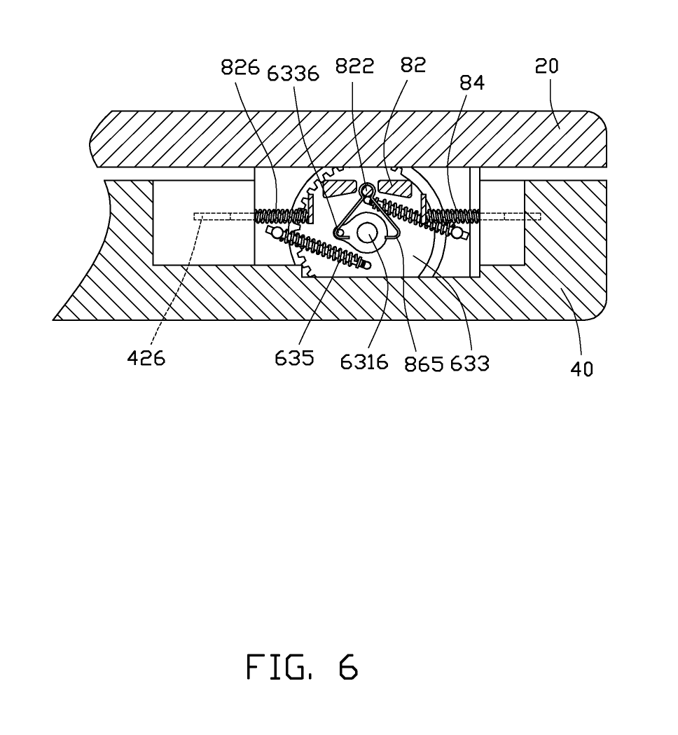

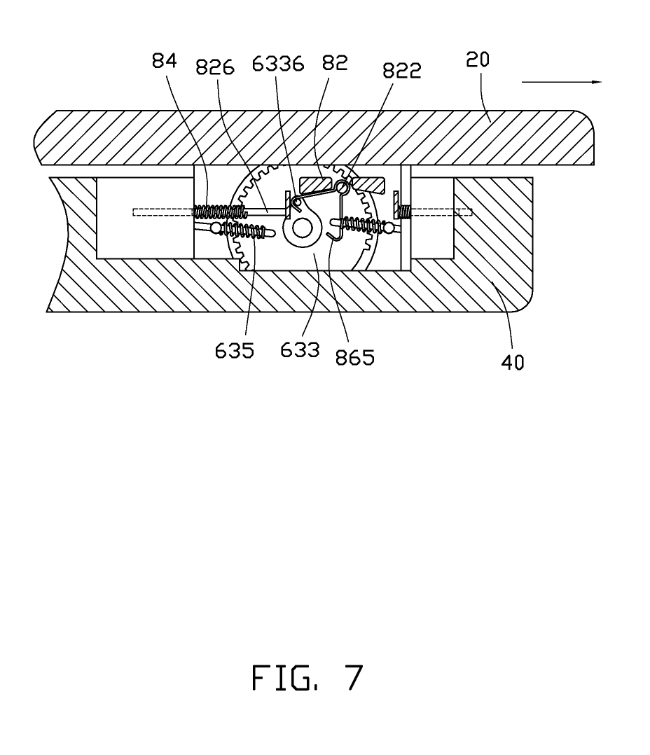

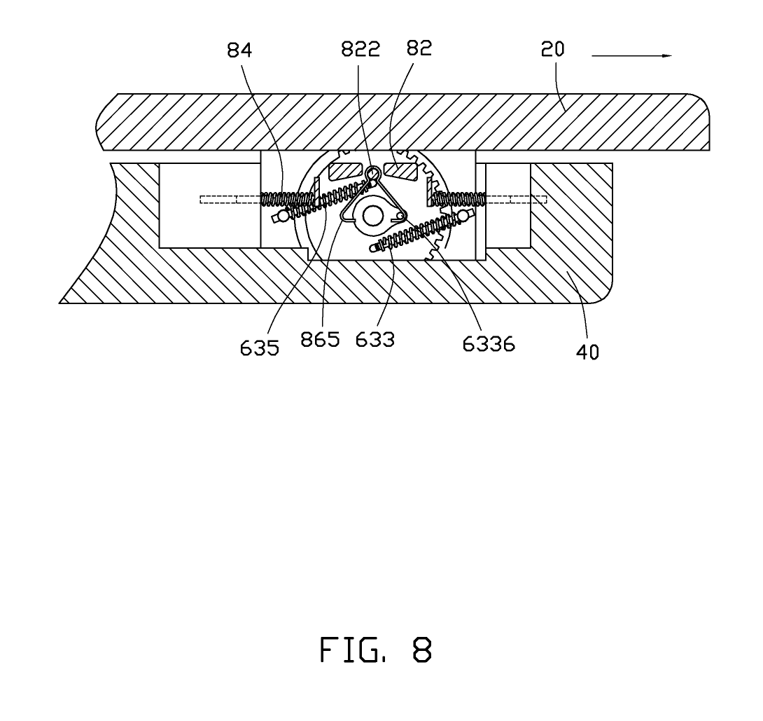

FIGS. 6-8 show that in use, the skid-proof bars 827 of the operation member 82 is pushed forward, to slide the sliding plate 821 forward along the guiding slot 424. The guiding poles 826 slide forward along the guiding holes 426. The second resilient member 6352 positioned at the front of the operation member 82 is pressed, to be deformed. The pole 6336 is latched in the hook 865 and positioned at a rear of the adjusting member 86. The pole 6336 is rotated up about the shaft 6316, to pivot the gear 633 clockwise. The gear 633 drives the rack 24 to move forward, to slide the display 20 forward relative to the base 40. The pivots 6355 pivot in the connecting holes 6335 of the gear 633, the rotating poles 6351 pivot in the rotation holes 6315 of the bracket 631, and the connecting poles 6356 pivot in the through holes 6358 of the rotating poles 6351. The rotating poles 6351 and the corresponding shrink-rings 6357 press first resilient members 6352 until the connecting poles 6356 are rotated to be in the same horizontal line. The operation member 82 is further pushed forward, to allow the connecting poles 6356 to misalign, and the adjusting member 86 is blocked by the corresponding tab 823. The first resilient members 6352 are restored to bias the connecting members 6354 to slide away from the corresponding rotating poles 6351. The connecting members 6354 drive the gear 633 to pivot clockwise. The gear 633 further drives the rack 24 to move forward, until the positioning bar 26 of the display 20 is blocked by the stopping bar 427 positioned on the front of the base 40. The operation member 82 is released, the second resilient member 84 positioned at the front of the operation member 82 is restored to bias the sliding plate 821 back, and the adjusting member 86 is pivoted back. The pole 6336 of the gear 633 is received in the hook 865 positioned at a front of the adjusting member 86.

When the display 20 needs to be closed, the skid-proof bars 827 are pulled rearward, to slide the sliding plate 821 rearward along the guiding slot 424. The guiding poles 826 slide rearward along the guiding holes 426. The second resilient member 6352 positioned at the rear of the operation member 82 is pressed, to be deformed. The pole 6336 is rotated up about the shaft 6316, to pivot the gear 633 anticlockwise. The gear 633 drives the rack 24 to move rearward. The display 20 is slid rearward relative to the base 40. The pivots 6355 pivot in the connecting holes 6335 of the gear 633, the rotating poles 6351 pivot in the rotation holes 6315 of the bracket 631, and the connecting poles 6356 pivot in the through holes 6358 of the rotating poles 6351. The rotating poles 6351 and the corresponding shrink-rings 6357 press the first resilient members 6352, until the connecting poles 6356 are rotated to be in the same horizontal line. The operation member 82 is further pulled rearward, to allow the connecting poles 6356 to misalign, and the adjusting member 86 is blocked by the corresponding tab 823.

The first resilient members 6352 are restored to bias the connecting members 6354 to slide away from the corresponding rotating poles 6351, to drive the gear 633 to pivot anticlockwise. The gear 633 further drives the rack 24 to move rearward, until the positioning bar 26 is blocked by the stopping bar 427 positioned on the rear of the base 40. The operation member 82 is released, the second resilient member 84 positioned at the rear of the operation member 82 is restored to bias the sliding plate 821 back, and the adjusting member 86 is pivoted back. The display 20 is fully closed on the base 40.

It is to be understood, however, that even though numerous characteristics and advantages of certain embodiments have been set forth in the foregoing description, together with details of the structures and functions of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. An electronic device, comprising:
a base;
a display slidably mounted on the base;
a slide apparatus installed between the base and the display, and comprising a rack mounted to the display, a gear pivotably installed in the base and engaging with the rack, and a pole protruding out from the gear, wherein an axis of the pole deviates from an axis of the gear; and
an operation apparatus comprising an operation member slidably installed to the base and an adjusting member rotatably connected between the operation member and the pole;
wherein when the operation member is slid, the adjusting member is driven to rotate the gear, thus sliding the display relative to the base.

2. The electronic device of claim 1, wherein the slide apparatus further comprises a bracket, the bracket comprises a top surface and a side surface extending down from the top surface, the side surface of the bracket defines a recess, the recess extends through the top surface of the bracket, the gear is pivotably received in the recess, with a part of the gear exposed out of the top surface of the bracket.

3. The electronic device of claim 2, wherein a shaft perpendicularly extends out from a middle of an inner wall of the recess opposite to the side surface, the gear axially defines a shaft hole, the shaft is pivotably inserted in the shaft hole of the gear.

4. The electronic device of claim 2, wherein the slide apparatus further comprises a resilient assembly connected between the gear and the bracket, the side surface of the bracket defines a rotation hole adjacent to the recess, the gear defines a connecting hole, the resilient assembly comprises a rotation pole pivotably connected in the rotation hole of the bracket, a connecting member, and a resilient member, a first end of the connecting member is pivotably connected in the connecting hole of the gear, a second end of the connecting member movably connected to the rotating pole, the resilient member is sandwiched between the connecting member and the rotating pole.

5. The electronic device of claim 4, wherein the connecting member comprises a pivot pivotably connected in the connecting hole and a connecting pole perpendicularly extending out from an end of the pivot, an end of the rotating pole defines a through hole, the resilient member is fit about the connecting pole, a distal end of the connecting pole is inserted in the through hole of the rotating pole.

6. The electronic device of claim 3, wherein a protrusion protrudes out from a middle of the gear, the shaft hole extends through the protrusion, the pole extends from the protrusion away from the shaft hole.

7. The electronic device of claim 6, wherein the operation member comprises a sliding plate and a connecting shaft protruding from a middle portion of the sliding plate toward the base, the adjusting member comprises a C-shaped rotation portion pivotably fitted about the connecting shaft, two connecting pieces slantingly extending down and away from each other from two opposite distal ends of the rotation portion, and two hooks formed on distal ends of the connecting pieces, the pole of the gear is operable of being latched with one of the hooks.

8. The electronic device of claim 7, wherein a top surface of the base defines a receiving space, the receiving space is located in a side of the base, the side of the base defines a guiding slot communicating with the receiving space, the bracket is received in the receiving space, the operation member is slidably received in the guiding slot.

9. The electronic device of claim 8, wherein the base defines two opposite guiding holes in a junction of the receiving space and the guiding slot, the operation member further comprises two pieces protruding out from the sliding plate and adjacent to the connecting shaft, and two guiding poles extending from the pieces away from each other, the guiding poles are slidably inserted in the guiding holes, the operation member further comprises two resilient members fitting about the guiding poles.

10. The electronic device of claim 7, wherein the operation member further comprises two spaced tabs protruding out from the sliding plate between the pieces, the connecting shaft is located between the tabs, the connecting pieces of the adjusting member are blocked between the tabs.

11. The electronic device of claim 1, wherein two spaced stopping bars protrude up from the base, a positioning bar protrudes down from the display, the positioning bar is stopped between the stopping bars of the base.
